(19) United States
(12) Patent Application Publication
(10) Pub. No.: US 2025/0293070 A1
(43) Pub. Date: Sep. 18, 2025

(54) Low Cost Electrostatic Chuck for Chucking Insulator Substrates

(71) Applicant: Applied Materials, Inc., Santa Clara, CA (US)

(72) Inventor: Vijay D. PARKHE, San Jose, CA (US)

(21) Appl. No.: 18/926,108

(22) Filed: Oct. 24, 2024

Related U.S. Application Data
(60) Provisional application No. 63/564,892, filed on Mar. 13, 2024.

(51) Int. Cl. H01L 21/683; H01J 37/32

(52) U.S. Cl. CPC H01L 21/6833; H01J 37/32715; H01J 2237/2007

(57) ABSTRACT

Methods of forming electrostatic chucks (ESCs) are provided herein. In some embodiments, a method of forming an electrostatic chuck (ESC) includes: forming a plurality of first grooves that are interconnected in a lower surface of a ceramic plate; forming a plurality of second grooves that are interconnected in the lower surface of the ceramic plate and that are separate from the plurality of first grooves; depositing a metal layer in the plurality of first grooves to form a first electrode and in the plurality of second grooves to form a second electrode; and filling the plurality of first grooves and the plurality of second grooves with a dielectric material.

### CROSS-REFERENCE TO RELATED APPLICATIONS

This application claims benefit of U.S. provisional patent application Ser. No. 63/564,892, filed Mar. 13, 2024, which is herein incorporated by reference in its entirety.

### FIELD

Embodiments of the present disclosure generally relate to substrate processing equipment.

### BACKGROUND

Integrated circuits are made possible by processes which produce intricately patterned material layers on substrate surfaces. Producing patterned material on a substrate requires controlled methods for applying and removing material. Typically, these methods include retaining a substrate or workpiece on a substrate support within a processing chamber, for example, using an electrostatic chuck (ESC), such as a bipolar ESC. However, the inventors have observed that conventional bipolar ESCs cannot effectively chuck high resistance substrates, such as epoxy, glass, or Si/glass substrates. For bipolar ESCs, a higher voltage potential is needed to enable chucking of high resistance substrates. However, the higher voltage potential may lead to issues such as high dielectric breakdown risk, reduced uniformity of backside gas pressure, uneven cooling, and difficulty in de-chucking the substrate. Additionally, ESCs are costly to manufacture using conventional methods. As such, large ESCs for chucking large substrates (e.g., >300 mm) become increasingly costly to manufacture.

Accordingly, the inventors have provided herein embodiments of improved ESCs and method of forming improved ESCs.

### SUMMARY

Methods of forming electrostatic chucks (ESCs) are provided herein. In some embodiments, a method of forming an electrostatic chuck (ESC) includes: forming a plurality of first grooves that are interconnected in a lower surface of a ceramic plate; forming a plurality of second grooves that are interconnected in the lower surface of the ceramic plate and that are separate from the plurality of first grooves; depositing a metal layer in the plurality of first grooves to form a first electrode and in the plurality of second grooves to form a second electrode; and filling the plurality of first grooves and the plurality of second grooves with a dielectric material.

Embodiments of electrostatic chucks are provided herein. In some embodiments, an electrostatic chuck (ESC) includes: one or more ESC panels, wherein each ESC panel comprises: a ceramic plate having a plurality of first grooves that are interconnected in a lower surface of a ceramic plate and a plurality of second grooves that are interconnected in the lower surface of the ceramic plate and that are separate from the plurality of first grooves; a first metal layer disposed in the plurality of first grooves to form a first electrode and a second metal layer disposed in the plurality of second grooves to form a second electrode; and a dielectric material disposed in the plurality of first grooves to enclose the first electrode and in the plurality of second grooves to enclose the second electrode.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a flow chart of forming an ESC in accordance with at least some embodiments of the present disclosure.

FIG. 2 depicts a flow chart of forming a multi-panel ESC in accordance with at least some embodiments of the present disclosure.

FIG. 3 depicts a schematic bottom view of a ceramic plate in accordance with at least some embodiments of the present disclosure.

FIG. 4 depicts a schematic cross-sectional side view taken along line 4-4 of FIG. 3 in accordance with at least some embodiments of the present disclosure.

FIG. 5 depicts a schematic cross-sectional side view taken along line 5-5 of FIG. 3 in accordance with at least some embodiments of the present disclosure.

FIG. 6 depicts a schematic isometric view of an ESC panel in accordance with at least some embodiments of the present disclosure.

FIG. 7 depicts a schematic bottom isometric view of a multi-panel ESC in accordance with at least some embodiments of the present disclosure.

FIG. 8A depicts a schematic bottom isometric view of a multi-panel ESC with a cooling plate in accordance with at least some embodiments of the present disclosure.

FIG. 8B depicts a schematic top isometric view of a multi-panel ESC in accordance with at least some embodiments of the present disclosure.

FIG. 9 depicts a schematic cross-sectional side view of a process chamber in accordance with at least some embodiments of the present disclosure.

FIG. 10A depicts a schematic cross-sectional top view of a multi-panel ESC in accordance with at least some embodiments of the present disclosure.

FIG. 10B depicts a schematic side view of a multi-panel ESC in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of electrostatic chucks (ESCs) and methods of forming ESCs are provided herein. The methods provided herein can advantageously produce ESCs that have high breakdown potential and that are effective at chucking high resistance substrates, or insulator substrates, such as epoxy, glass, or Si/glass substrates. The methods provided herein can also advantageously be used to form large ESCs at a lower cost. For example, the methods provided herein can form ESCs for chucking substrates having a diameter or width larger than 300 mm, such as 500 mm or greater. The methods provided herein may advantageously form ESC without the use of high temperature processes such as with the use of a furnace.

The methods provided herein can generally form one or more electrodes in a ceramic plate via deposition of a metal layer in grooves formed in a lower surface of the ceramic plate. The one or more electrodes may be one electrode to form a monopolar ESC. In some embodiments, the one or more electrodes may be two electrodes to form a bipolar ESC. In some embodiments, the one or more electrodes can be 3 or more electrodes, such as between 3 to 18 electrodes. For example, the 3 or more electrodes can be arranged in sets so that more or less electrostatic chucking force can be applied to different regions of a substrate being chucked. Such an arrangement advantageously allows for improved flattening of the substrate. For example, the ceramic plate may include a center electrode, four middle electrodes, and four outer electrodes. In some embodiments, the ceramic plate may include two center electrodes, eight middle electrodes, and eight outer electrodes. A chucking sequence for a substrate can comprise chucking a center of the substrate with the center electrode, then a radially middle region of the substrate with the middle electrodes, and then an edge region of the substrate with the outer electrodes. In other embodiments, the chucking sequence may include chucking from one side of the substrate to an opposing side in sequence. A de-chucking sequence may comprise performing the chucking sequence in reverse.

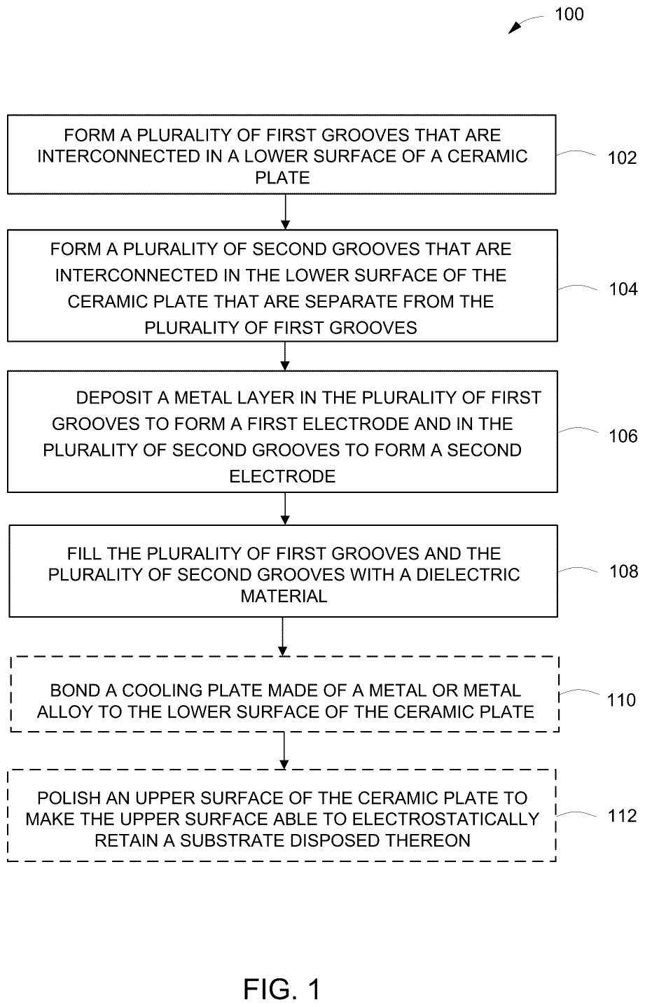

FIG. 1 depicts a flow chart of a method 100 of forming an ESC in accordance with at least some embodiments of the present disclosure. At 102, the method 100 includes forming a plurality of first grooves (e.g., plurality of first grooves 304) that are interconnected in a lower surface (e.g., lower surface 315) of a ceramic plate (e.g., ceramic plate 302). At 104, the method 100 includes forming a plurality of second grooves (e.g., plurality of second grooves 306) that are interconnected in the lower surface of the ceramic plate that are separate from the plurality of first grooves. In some embodiments, forming the plurality of first grooves and the plurality of second grooves is performed via saw dicing, laser machining, or ultrasonic machining. The plurality of first grooves and the plurality of second grooves extend only partially through a thickness of the ceramic plate so that ceramic material remains between an upper surface (e.g., upper surface 425) of the ceramic plate and the plurality of first grooves and the plurality of second grooves. In some embodiments, forming the plurality of first grooves and the plurality of second grooves is performed by depositing a ceramic material on the lower surface of the ceramic plate, where the ceramic material defines the plurality of first grooves and the plurality of second grooves.

In some embodiments, the method 100 includes forming additional plurality of grooves as discussed above that are interconnected and separate from the plurality of first grooves and the plurality of second grooves to facilitate chucking and de-chucking sequences. For example, in some embodiments, the method 100 includes forming a plurality of third grooves that are interconnected in the lower surface of the ceramic plate. In some embodiments, the additional plurality of grooves comprises one to sixteen additional plurality of grooves so that the ESC has a total of eighteen separate electrodes. Other embodiments could include additional grooves and electrodes.

In some embodiments, the ESC is configured to hold a substrate having a diameter or width of about 300 to about 9000 mm, for example about 500 mm. In some embodiments, the ESC has a rectangular or square shape. In some embodiments, the ESC has a rounded shape, such as a circular shape. Other shapes for the ESC may also be possible. In some embodiments, the ceramic plate has a thickness less than 3.0 mm, for example, about 0.5 mm to about 1.0 mm. In some embodiments, the ceramic plate is a solid plate or a sintered plate. In some embodiments, the ceramic plate is a green plate that needs to be sintered to solidify. In such embodiments, the method 100 includes sintering the green plate prior to forming the plurality of first grooves and the plurality of second grooves. In some embodiments, the ceramic plate is made of aluminum oxide or aluminum nitride.

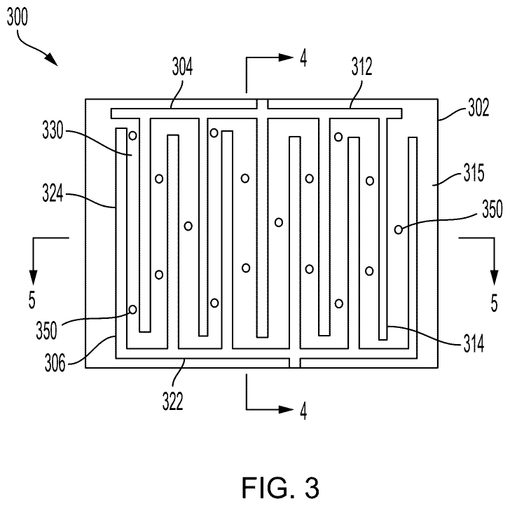

FIG. 3 depicts a schematic bottom view of a ceramic plate in accordance with at least some embodiments of the present disclosure. An ESC 300 includes the ceramic plate 302 having a plurality of first grooves 304 and a plurality of second grooves 306 disposed in a lower surface 315 of the ceramic plate 302. The plurality of first grooves 304 are interconnected, and the plurality of second grooves 306 are interconnected. In some embodiments, the plurality of first grooves 304 and the plurality of second grooves 306 have a depth of about 400 to about 800 microns, for example, between about 500 to about 700 microns. The plurality of first grooves 304 and the plurality of second grooves 306 are separate and are arranged so that there is a gap 330 therebetween. The gap 330 is generally suitably large enough to prevent arcing and small enough to provide sufficient chucking force. In some embodiments, the gap 330 is between about 0.3 mm to about 2.0 mm. In some embodiments, the gap 330 is between about 0.3 mm to about 3.0 mm. The plurality of first grooves 304 and the plurality of second grooves 306 may include linear or straight grooves, curved grooves, or a combination thereof.

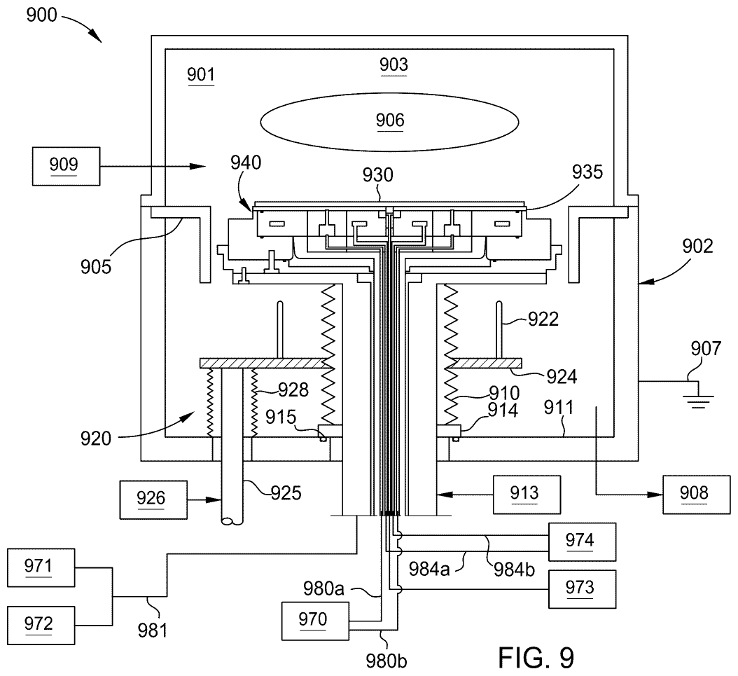

In some embodiments, the plurality of first grooves 304 include a first base groove 312 and plurality of first finger grooves 314 extending from the first base groove 312. In some embodiments, the plurality of second grooves 306 include a second base groove 322 and a plurality of second finger grooves 324 extending from the second base groove 322. In some embodiments, the plurality of first finger grooves 314 and the plurality of second finger grooves 324 are generally alternately arranged such that individual first finger grooves are disposed between adjacent individual second finger grooves and individual second finger grooves are disposed between adjacent individual first finger grooves. In some embodiments, the plurality of first finger grooves 314 have a width of 0.2 mm to 1.1 mm. In some embodiments, the plurality of second finger grooves 324 have a width of 0.2 mm to 1.1 mm. In some embodiments, a plurality of vacuum holes 350 extend through the ceramic plate 302. The plurality of vacuum holes 350 may extend in any suitable manner from an upper surface of the ceramic plate 302 to the lower surface 315 of the ceramic plate 302. The plurality of vacuum holes 350 are configured for vacuum chucking a substrate (discussed in more detail below). For example, the plurality of vacuum holes 350 are fluidly coupled to a pump (see pump 973 in FIG. 9). In some embodiments, the plurality of vacuum holes 350 are disposed between the plurality of first grooves 304 and the plurality of second grooves 306.

At 106, the method 100 includes depositing a metal layer (e.g., first metal layer 410) in the plurality of first grooves to form a first electrode (e.g., first electrode 420) and a metal layer (e.g., second metal layer 414) in the plurality of second grooves to form a second electrode (e.g., second electrode 430). In some embodiments, the method 100 includes depositing the metal layer in the plurality of third grooves and any additional grooves to form a third electrode and any additional electrodes. Forming the first electrode and the second electrode via a backside of the ceramic plate (e.g., via the plurality of first grooves and the plurality second grooves) advantageously provides higher breakdown potential, for example, than forming the first electrode and the second electrode via depositing a metal layer on an upper surface of a ceramic plate. In some embodiments, the metal layer has a thickness of about 1 to about 550 microns. In some embodiments, the metal layer comprises a metallic ink or metallic paste comprising aluminum, titanium, tungsten, molybdenum, platinum, or an alloy thereof. The metallic ink generally has a lower viscosity than a metallic paste and may be advantageously used when lower viscosity is important.

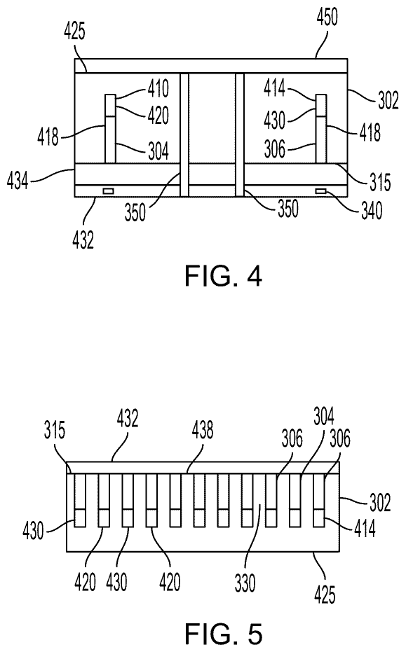

FIG. 4 depicts a schematic cross-sectional side view taken along line 4-4 depicted in FIG. 3 in accordance with at least some embodiments of the present disclosure. FIG. 5 depicts a schematic cross-sectional side view taken along line 5-5 depicted in FIG. 3 in accordance with at least some embodiments of the present disclosure. The ceramic plate 302 includes a first metal layer 410 disposed in the plurality of first grooves 304 to form a first electrode 420 and a second metal layer 414 disposed in the plurality of second grooves 306 to form a second electrode 430. In some embodiments, a distance between the first electrode 420 and the second electrode 430 is between about 0.5 to about 2.0 mm.

At 108, the method 100 includes filling the plurality of first grooves and the plurality of second grooves with a dielectric material. The dielectric material 418 may be any suitable dielectric material such as a ceramic paste, glue, or slurry. In some embodiments, the dielectric material comprises a material such as silicone paste, polyimide, acrylic, a plasma spray ceramic material, alumina, compounds comprising aluminum or yttrium, epoxy, or the like. As depicted in FIGS. 4 and 5, a dielectric material 418 may be disposed in the plurality of first grooves 304 to enclose or embed the first electrode 420 in the ceramic plate 302 and in the plurality of second grooves 306 to enclose or embed the second electrode 430 in the ceramic plate 302. The first electrode 420 and the second electrode 430 are configured to chuck the substrate 450 to the ceramic plate 302. In some embodiments, the method 100 includes filling the plurality of third grooves and any additional grooves with the dielectric material to enclose or embed the third electrode and any additional electrodes in the ceramic plate.

In some embodiments, at 110, the method 100 further comprises bonding a cooling plate (e.g., cooling plate 432) made of a metal or metal alloy to the lower surface of the ceramic plate. In some embodiments, as shown in FIG. 4, the method 100 further comprises bonding the cooling plate 432 to the ceramic plate 302 via a second ceramic plate (e.g., second ceramic plate 434) disposed therebetween. The cooling plate 432 may include channels 340 for flowing a coolant fluid therethrough. In some embodiments, the cooling plate 432 comprises aluminum. The cooling plate may advantageously cool, or regulate a temperature of, the ceramic plate 302.

The second ceramic plate 434 may advantageously enhance heat removal from the ceramic plate 302. The second ceramic plate 434 may also further isolate the first electrode 420 and the second electrode 430 from ground, thereby reducing or preventing arcing. Moreover, the second ceramic plate 434 may advantageously provide additional structural rigidity to the ceramic plate 302. In some embodiments, the second ceramic plate 434 has a thickness of about 0.4 to about 0.6 mm.

In some embodiments, the cooling plate 432 may be bonded or glued to the ceramic plate 302 directly without the second ceramic plate 434. In some embodiments, the lower surface 315 of the ceramic plate 302 has a plasma spray coating 438 and the cooling plate 432 is coupled to the lower surface 315 with the plasma spray coating 438 disposed therebetween. The plasma spray coating 438 may comprise a ceramic material. The plasma spray coating 438 may be used in lieu of the second ceramic plate 434 if sufficient to reduce or prevent arcing. In some embodiments, the cooling plate 432 may be bonded or glued to the ceramic plate 302 directly without either the second ceramic plate 434 or the plasma spray coating 438, for example, if arcing is not an issue or the glue provides sufficient protection against arcing.

In some embodiments, the method 100 includes forming a plurality of vacuum holes (e.g., plurality of vacuum holes 350) through the ceramic plate 302 to provide vacuum chucking. In some embodiments, the plurality of vacuum holes extend through the ceramic plate 302 and the cooling plate 432. The vacuum holes may be disposed in any suitable arrangement. In some embodiments, the plurality of vacuum holes have a diameter of about 0.5 to about 3.0 mm. In some embodiments, a spacing between the plurality of vacuum holes and an adjacent one of the plurality of first grooves or the plurality of second grooves is about 0.2 to about 0.7 mm. The vacuum holes may be coupled to a pump in a suitable manner to provide a suction force on the substrate 450 through the vacuum holes to vacuum chuck the substrate 450. The suction force may advantageously provide additional clamping force for flattening substrates that are bowed or warped.

In use, vacuum chucking may be used to flatten a substrate, followed by electrostatic chucking via the electrodes disposed in the ceramic plate to hold the substrate. Then, vacuum chucking may then be turned off as process pressure in a process chamber is lowered, making vacuum force negligible, so that the electrostatic force holds the substrate. For de-chucking, a reverse procedure may be used.

In some embodiments, at 112, the method 100 includes polishing an upper surface of the ceramic plate to make the upper surface able to electrostatically retain a substrate disposed thereon. In some embodiments, polishing the upper surface of the ceramic plate is performed until a distance between the upper surface and the first electrode and the second electrode is about 200 to about 800 microns. Such a distance is advantageously small enough for electrostatically retaining of the substrate and large enough to reduce or prevent cracking or breaching of the ceramic material of the ceramic plate 302.

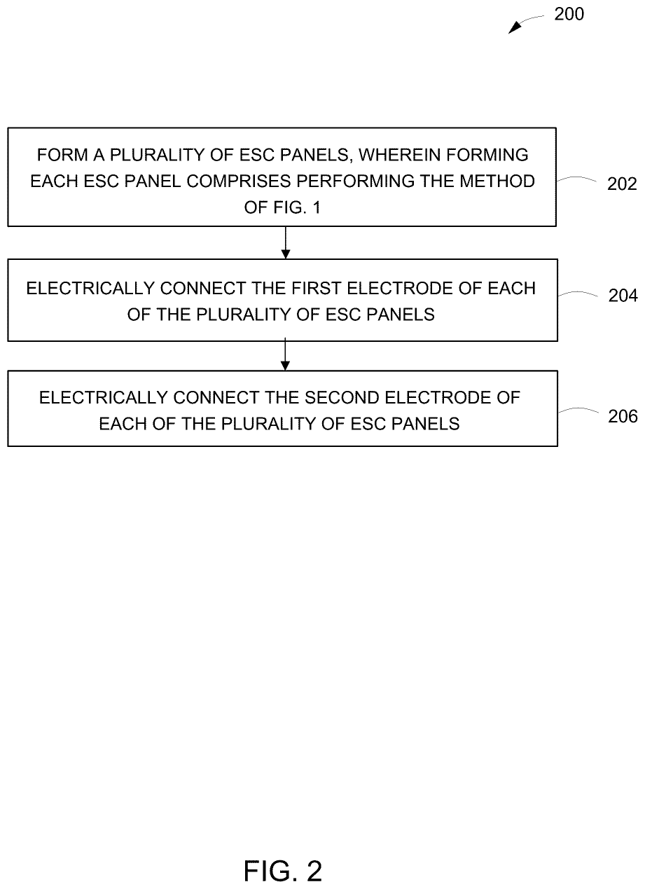

FIG. 2 depicts a flow chart of a method 200 of forming a multi-panel ESC (e.g., multi-panel ESC 700) in accordance with at least some embodiments of the present disclosure. At 202, the method 200 includes forming a plurality of ESC panels (e.g., plurality of ESC panels 600), wherein forming each ESC panel comprises the method 100 discussed above. The plurality of ESC panels may comprise a suitable number of panels to form a variety of shapes and sizes, such as rectangular, circular, or the like. In some embodiments, the plurality of ESC panels comprise 4 to 9 ESC panels that together form a rectangular or square shaped multi-panel ESC. The multi-panel ESC advantageously allows for the formation of a large format ESC without the need for large process chambers or furnaces to accommodate a size of the large format ESC.

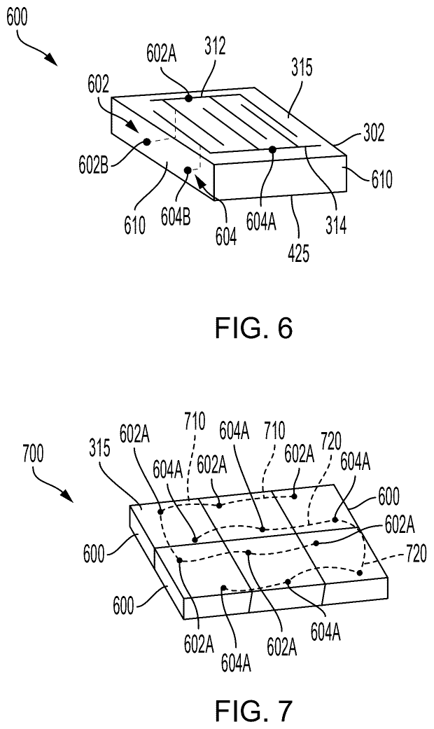

FIG. 6 depicts a schematic isometric view of an ESC panel 600 in accordance with at least some embodiments of the present disclosure. In some embodiments, the ESC panel 600 is the ESC 300. A first terminal 602 may be electrically coupled to the first electrode 420. The first terminal 602 generally facilitates electrical coupling of multiple ESC panels. In some embodiments, the first terminal 602 includes a first terminal 602A disposed on the lower surface 315 of the ceramic plate 302 for lower side electrical coupling of multiple ESC panels. In some embodiments, the first terminal 602 includes a first terminal 602B disposed on a sidewall 610 of the ceramic plate 302 for sidewall electrical coupling of multiple ESC panels. Accordingly, the first terminal 602 of multiple ones of the ESC panel 600 may be electrically coupled to form a positive or negative electrode of the large format ESC.

A second terminal 604 may be electrically coupled to the second electrode 430. The second terminal 604 generally facilitates electrical coupling of multiple ESC panels. In some embodiments, the second terminal 604 includes a second terminal 604A disposed on the lower surface 315 of the ceramic plate 302 for lower side electrical coupling of multiple ESC panels. In some embodiments, the second terminal 604 includes a second terminal 604B disposed on the sidewall 610 of the ceramic plate 302 for sidewall electrical coupling of multiple ESC panels. The second terminal 604 of multiple ones of the ESC panel 600 may be electrically coupled to form a positive or negative electrode of the large format ESC. Each of the plurality of ESC panels 600 may be a suitable size, such as about 250 mm to about 450 mm in diameter or width.

FIG. 7 depicts a schematic bottom isometric view of a multi-panel ESC 700 in accordance with at least some embodiments of the present disclosure. The multi-panel ESC 700 is formed by electrically coupling the plurality of ESC panels 600. At 204, the method 200 includes electrically connecting the first electrode (e.g., first electrode 420) of each of the plurality of ESC panels. As shown in FIG. 7, the first electrode of each of the plurality ESC panels 600 are connected via first conduits 710. At 206, the method 200 includes electrically connecting the second electrode (e.g., second electrode 430) of each of the plurality of ESC panels.

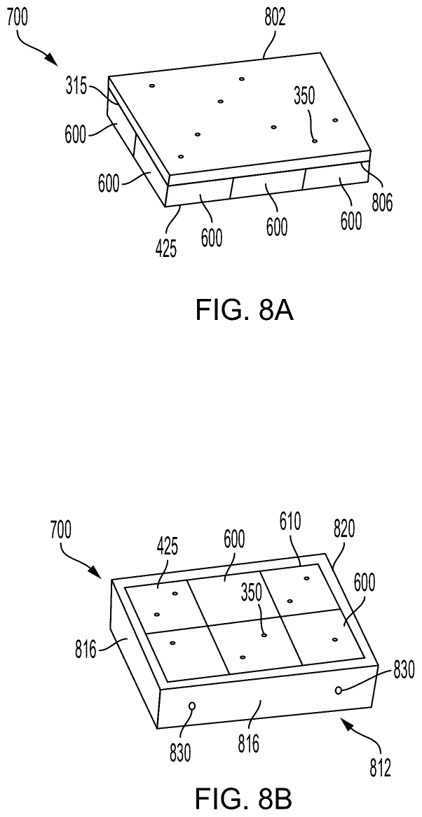

In some embodiments, the method 200 further comprises attaching a cooling plate (e.g., cooling plate 802) to the plurality of ESC panels 600, as shown in FIG. 8. FIG. 8 depicts a schematic bottom isometric view of a multi-panel ESC 700 with a cooling plate 802 coupled to the plurality of ESC panels 600 in accordance with at least some embodiments of the present disclosure. The cooling plate 802 may be a single plate that is coupled to all of the plurality of ESC panels 600. In other embodiments, the cooling plate 802 may comprise a plurality of cooling plates, where each of the plurality of cooling plates are coupled to one or more of the plurality of ESC panels 600.

In some embodiments, the method 200 includes attaching a second ceramic layer (e.g., second ceramic layer 806) to the cooling plate 802 or lower surface of the plurality of ESC panels 600 prior to attaching the cooling plate 802 to the plurality of ESC panels 600. The cooling plate 802 is a metal cooling plate that may serve a similar purpose as the cooling plate 432 discussed above for the multi-panel ESC 700. The second ceramic layer 806 may serve a similar purpose as the second ceramic plate 434 or the plasma spray coating 438 discussed above.

In some embodiments, as depicted in FIG. 8B, the method 200 includes placing the plurality of ESC panels 600 in a tray 820 to secure the plurality of ESC panels 600. In some embodiments, the plurality of ESC panels 600 are flipped into the tray 820 so that the upper surface 425 of each of the plurality of ESC panels is exposed. FIG. 8B depicts a schematic top isometric view of a multi-panel ESC 700 in accordance with at least some embodiments of the present disclosure. The tray 820 generally covers and protects the sidewalls 610 of each of the plurality of ESC panels 600. For example, in some embodiments, the tray 820 includes a base plate 812 and sidewalls 816 extending from the base plate 812. The tray 820 may include openings 830 for a power feedthrough to the first electrode 420 and the second electrode 430. In some embodiments, the upper surface of the sidewalls 816 are coplanar with the upper surface 425 of each of the plurality of ESC panels 600.

FIG. 9 depicts a schematic cross-sectional side view of a process chamber in accordance with at least some embodiments of the present disclosure. In some embodiments, the process chamber 900 is a pre-clean or deposition chamber. However, process chamber 900 can be configured to complete other processes suitable for semiconductor fabrication and processing. The process chamber 900 is suitably adapted to maintain a processing pressure therein during substrate processing. The process chamber generally includes a chamber body 902 that defines an interior volume 901 therein. A processing volume 903 is located in an upper portion of the interior volume 901. The processing volume 903 may be maintained at sub-atmospheric pressures during processing. The process chamber 900 may also include one or more shields 905 circumscribing various chamber components to prevent unwanted reaction between such components and ionized process material. The chamber body 902 may be made of metal, such as aluminum. The chamber body 902 may also be connected to a ground 907.

The process chamber 900 includes an exhaust 908 to remove gases from the interior volume 901. The processing pressure may be maintained and/or adjusted using the exhaust 908. The exhaust 908 may include one or more pumps. For example, the exhaust may include a throttle valve and vacuum pump. In some embodiments, the exhaust 908 is used to maintain the processing volume 903 at sub-atmospheric conditions. The process chamber 900 is coupled to a gas supply 909 which introduces gases, such as one or more process gases, into the processing volume 903. One or more gases delivered into the processing volume 903 may be ignited into and maintained as a plasma 906 by a substrate support 940.

The substrate support 940 is at least partially disposed within the interior volume 901 for supporting and chucking a substrate 930. The substrate 930 is placed on an ESC 935 of the substrate support 940. The ESC 935 may be the ESC 300 or multi-panel ESC 700 discussed above. A chucking power source 970 is coupled to chucking electrodes (e.g., first electrode 420, second electrode 430) in the substrate support 940 by electrical lines 980a and 980b to provide power necessary to chuck the substrate 930 to the substrate support 940. The electrical lines 980a and 980b may be coupled to electronic switches to energize chucking and de-chucking sequences. The chucking power source 970 may include additional electrical lines and associated electronic switches to provide power to additional chucking electrodes (e.g., third electrode, fourth electrode) and to perform chucking and de-chucking sequences.

A first RF power supply 971 is connected to the substrate support 940 via a conduit 981 to provide power to ignite the gases within the processing volume 903 to form the plasma 906. A second RF power supply 972 may be connected to the substrate support 940 via the conduit 981 (or separate conduit) to further excite the plasma 906 and to control the plasma 906 during processing of the substrate 930. A pump 973 may be connected to the plurality of vacuum holes 350 in the substrate support 940 via pump line 983 to provide vacuum suction to the substrate 930. A heat exchanger 974 may be connected to the substrate support 940 to circulate a coolant fluid into the substrate support 940 to regulate the temperature of the substrate 930. The coolant fluid flows into the substrate support 940 (e.g., cooling plate 432) through a coolant supply line 984a that returns to the heat exchanger 974 through a coolant return line 984b.

The substrate support 940 may be coupled to a first lift mechanism 913 which provides vertical movement of the substrate support 940 between an upper, processing position (as shown in FIG. 1) and a lower, transfer position (not shown). A bellows assembly 910 is coupled to the substrate support 940 to provide a flexible seal that allows vertical motion of the substrate support 940 while preventing fluid communication between an environment outside the process chamber 900 and the interior volume 901. The bellows assembly 910 may also include a lower bellows flange 914 that is sealed against a bottom surface 911 of the chamber body 902 by one or more seals 915.

The process chamber 900 may also include a lift pin assembly 920 which includes one or more lift pins 922 mounted on a platform 924 connected to a shaft 925. The shaft 925 is coupled to a second lift mechanism 926 for selectively raising and lowering the lift pin assembly 920 relative to the substrate support 940 so that the substrate 930 may be placed on or removed from the electrostatic chuck 250. The substrate support 940 includes openings to receive the lift pins 922 such that the lift pins 922 can engage the underside of the substrate 930. A second bellows assembly 128 may be coupled between the lift pin assembly 920 and the bottom surface 911 to provide a flexible seal which maintains processing pressure during the vertical motion of the lift pin assembly 920.

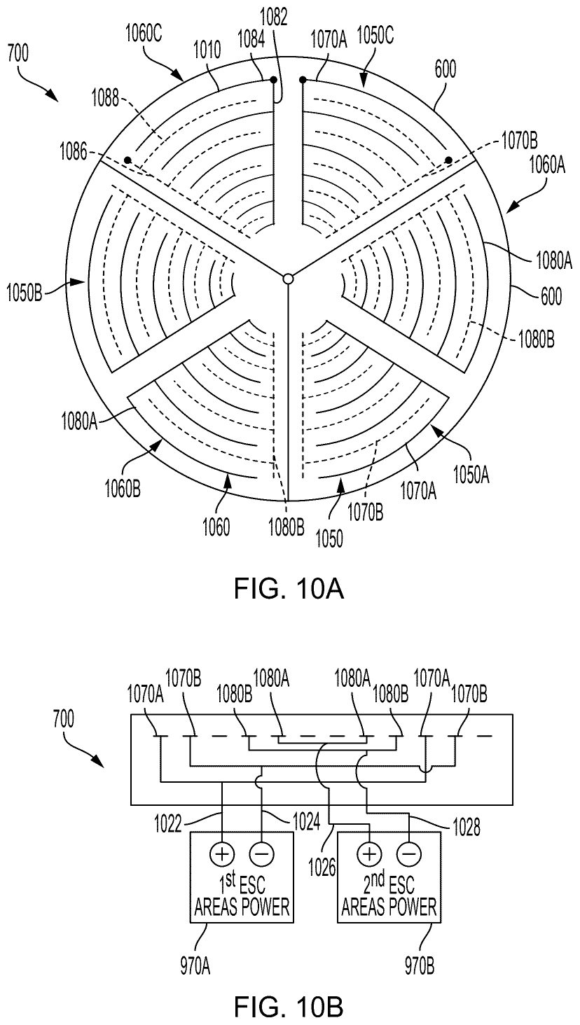

FIG. 10A depicts a schematic cross-sectional top view of a multi-panel ESC 700 that forms a circular shape in accordance with at least some embodiments of the present disclosure. FIG. 10B depicts a schematic side view of a multi-panel ESC 700 in accordance with at least some embodiments of the present disclosure. In some embodiments, the method 100 or the method 200 includes depositing the metal layer to define more than two electrodes. For example, the each of the ESC panels 600, or the multi-panel ESC 700 may comprise more than two electrodes. In some embodiments, the disclosure related to FIGS. 10A and 10B provided herein (e.g., arrangement of the plurality of chucking electrodes, or the like) may be applied to a single panel ESC such as the ESC 300.

As depicted in FIG. 10A, the multi-panel ESC 700 may comprise a plurality of chucking electrodes 1010 that define two ESC areas, a plurality of first ESC areas 1050 and a plurality of second ESC areas 1060. In some embodiments, each first ESC area of the plurality of first ESC areas 1050 is arranged in an alternating manner with a second ESC area of the plurality of second ESC areas 1060. In some embodiments, each first ESC area and each second ESC area comprise a plurality of wedge or pie shaped regions. Each first ESC area and second ESC area may comprise a positive electrode and a negative electrode arranged in an alternating pattern having a distance therebetween similar to as discussed above with respect to the first electrode 420 and the second electrode 430.

For example, as shown in FIG. 10A, the multi-panel ESC 700 may include three first ESC areas 1050A-C and three second ESC areas 1060A-C. Each of the first ESC areas 1050A-C may include a positive electrode 1070A arranged in an alternating pattern with a negative electrode 1070B. Each of the second ESC areas 1060A-C may include a positive electrode 1080A arranged in an alternating pattern with a negative electrode 1080B. The positive electrode 1080A and the positive electrode 1070A may be arranged in any suitable pattern. The negative electrode 1080B and the negative electrode 1070B may be arranged in any suitable pattern. For example, positive electrode 1080A may include a radially extending member 1082 and a plurality of annular members 1084 extending from the radially extending member 1082. For example, negative electrode 1080B may include a radially extending member 1086 and a plurality of annular members 1088 extending from the radially extending member 1086. In some embodiments, the plurality of annular members 1084 are curved and the radially extending members 1082 are straight.

In some embodiments, as shown in FIG. 10B, the positive electrode 1070A of multiple first areas of the plurality of first ESC areas 1050 may be electrically coupled to form a first electrode 1022. The negative electrode 1070B of multiple first areas of the plurality of first ESC areas 1050 may be electrically coupled to form a second electrode 1024. The positive electrode 1080A of multiple second areas of the plurality of second ESC areas 1060 may be electrically coupled to form a third electrode 1026. The negative electrode 1080B of multiple second areas of the plurality of second ESC areas 1060 may be electrically coupled to form a fourth electrode 1028. In some embodiments, the first electrode 1022 and the second electrode 1024 may form a first bipolar ESC that may provide a chucking force independent of a chucking force provided by a second bipolar ESC formed by the third electrode 1026 and the fourth electrode 1028. A first chucking power supply 970A may supply power to the first electrode 1022 and the second electrode 1024. A second chucking power supply 970B may supply power to the third electrode 1026 and the fourth electrode 1028. The multiple first ESC areas may be electrically coupled via a suitable manner within the multi-panel ESC 700 or outside of the multi-panel ESC 700. The multiple second ESC areas may be electrically coupled via a suitable manner within the multi-panel ESC 700 or outside of the multi-panel ESC 700.

While the foregoing is directed to embodiments of the present disclosure, other and further embodiments of the disclosure may be devised without departing from the basic scope thereof. The term about used herein may, in some embodiments, refer to a value within ten percent of the stated value. In some embodiments, the term about may refer to a value within fifteen percent of the stated value.

1. A method of forming an electrostatic chuck (ESC), comprising:
forming a plurality of first grooves that are interconnected in a lower surface of a ceramic plate;
forming a plurality of second grooves that are interconnected in the lower surface of the ceramic plate and that are separate from the plurality of first grooves;
depositing a metal layer in the plurality of first grooves to form a first electrode and in the plurality of second grooves to form a second electrode; and
filling the plurality of first grooves and the plurality of second grooves with a dielectric material.

2. The method of claim 1, further comprising:
forming a plurality of third grooves that are interconnected in the lower surface of the ceramic plate;
depositing the metal layer in the plurality of third grooves to form a third electrode; and
filling the plurality of third grooves with the dielectric material.

3. The method of claim 1, wherein forming the plurality of first grooves and the plurality of second grooves is performed via saw dicing, laser machining, or ultrasonic machining.

4. The method of claim 1, further comprising:
bonding a cooling plate made of a metal or metal alloy to the lower surface of the ceramic plate; and
bonding a second ceramic plate to the cooling plate.

5. The method of claim 1, wherein forming the plurality of first grooves and the plurality of second grooves is performed by depositing a ceramic material on the lower surface of the ceramic plate.

6. The method of claim 1, further comprising polishing an upper surface of the ceramic plate to make the upper surface able to electrostatically retain a substrate disposed thereon.

7. The method of claim 1, wherein the metal layer comprises a metallic ink or metallic paste comprising aluminum, titanium, tungsten, molybdenum, platinum, or an alloy thereof.

8. The method of claim 1, wherein at least one of:
the ceramic plate has a thickness of about 0.5 mm to about 3.0 mm, or
the ceramic plate is a sintered plate.

9. The method of claim 1, further comprising forming a plurality of vacuum holes through the ceramic plate to provide vacuum chucking.

10. The method of claim 1, wherein the dielectric material comprises a silicone paste, polyimide, acrylic, a plasma spray ceramic material, alumina, compounds comprising aluminum or yttrium, or epoxy.

11. A method of forming a multi-panel ESC, comprising:
forming a plurality of ESC panels, wherein forming each ESC panel comprises forming the ESC of claim 1, and further comprising:
electrically connecting the first electrode of each of the plurality of ESC panels; and
electrically connecting the second electrode of each of the plurality of ESC panels.

12. The method of claim 11, further comprising attaching a cooling plate to the plurality of ESC panels.

13. The method of claim 11, further comprising placing the plurality of ESC panels in a tray to secure the plurality of ESC panels.

14. The method of claim 11, wherein the plurality of ESC panels comprise 4 to 9 ESC panels.

15. An electrostatic chuck (ESC), comprising:
one or more ESC panels, wherein each ESC panel comprises:
a ceramic plate having a plurality of first grooves that are interconnected in a lower surface of a ceramic plate and a plurality of second grooves that are interconnected in the lower surface of the ceramic plate and that are separate from the plurality of first grooves;
a first metal layer disposed in the plurality of first grooves to form a first electrode and a second metal layer disposed in the plurality of second grooves to form a second electrode; and
a dielectric material disposed in the plurality of first grooves to enclose the first electrode and in the plurality of second grooves to enclose the second electrode.

16. The ESC of claim 15, wherein the one or more ESC panels comprises a plurality of ESC panels, wherein the first electrode of each of the one or more ESC panels are electrically coupled, and wherein the second electrode of each of the one or more ESC panels are electrically coupled.

17. The ESC of claim 16, further comprising a tray that includes a base plate and sidewalls extending from the base plate, wherein the plurality of ESC panels are disposed in the tray.

18. The ESC of claim 15, further comprising a metal cooling plate coupled to the lower surface of each of the one or more ESC panels.

19. The ESC of claim 18, further comprising a second ceramic plate coupled to each of the one or more ESC panels and disposed between the one or more ESC panels and the metal cooling plate.

20. The ESC of claim 15, wherein a distance between the first electrode and the second electrode is between about 0.3 to about 3.0 mm.
